(19) United States
(12) Patent Application Publication
(10) Pub. No.: US 2025/0185290 A1
(43) Pub. Date: Jun. 5, 2025

(54) SEMICONDUCTOR DEVICE AND METHOD FOR PREPARING SAME

(71) Applicants: Huizhou China Star Optoelectronics Display Co., Ltd., Huizhou, Guangdong (CN); TCL China Star Optoelectronics Technolagy Co., Ltd., Shenzhen, Guangdong (CN)

(72) Inventor: Daobing HU, Huizhou, Guangdong (CN)

(73) Assignees: Huizhou China Star Optoelectronics Display Co., Ltd., Huizhou, Guangdong (CN); TCL China Star Optoelectronics Technology Co., Ltd., Shenzhen, Guangdong (CN)

(21) Appl. No.: 17/600,246

(22) PCT Filed: Jun. 22, 2021
(86) PCT No.: PCT/CN2021/101402

§ 371 Date: Mar. 8, 2024

(30) Foreign Application Priority Data
Jun. 7, 2021 (CN) 202110629782.5

(51) Int. Cl. H10D 30/67; H01L 21/02; H10D 30/01; H10D 64/23

(52) U.S. Cl. CPC H10D 30/6728; H01L 21/02675; H10D 30/0318; H10D 30/6736; H10D 64/252

(57) ABSTRACT

The present disclosure provides a semiconductor device and a method for preparing same. The semiconductor device includes a substrate, a source, a semiconductor layer, a drain, an insulating layer, and a gate. A main body portion of the source and a main body portion of the drain are disposed on different faces. The semiconductor layer is disposed between the source and the drain. The gate is disposed on a side of the semiconductor layer. Therefore, a vertical channel thin film transistor (TFT) is formed. In this way, the mobility of carriers in the TFT and the performance of the semiconductor device are effectively improved.

### FIELD OF INVENTION

The present disclosure relates to the technical field of display panel manufacturing, and in particular, to a semiconductor device and a method for preparing a semiconductor device.

### BACKGROUND OF INVENTION

With the continuous improvement of display technologies, new display products have increasingly higher requirements for the display technology. Especially in a large-size 8K rollable high-end display product, higher requirements are also required for the drive capability of the display back panel.

A semiconductor device, such as a display panel, generally includes an array base plate. The array base plate includes a thin film transistor (TFT). A common TFT includes a self-aligned top-gate TFT. The self-aligned top-gate TFT includes an active layer. The active layer may be divided into a high-resistance area corresponding to a gate electrode and a low-resistance area corresponding to a source/drain. Because the gate electrode and the low-resistance area in the active layer do not overlap, there is a small parasitic capacitance between the gate electrode and the active layer, which can reduce the resistance of the active layer, thereby reducing a signal delay and improving the display effect. Therefore, the TFT is widely used in a high-resolution and large-size display panel. However, the currently prepared TFT still has specific problems, such as low mobility and poor stability. In addition, during the preparation of the TFT, the array base plate is limited by the complicated manufacturing process, resulting in high production costs. In this way, it is difficult to meet the requirement for a larger size.

Therefore, it is necessary to provide solutions to the problems in the prior art.

### SUMMARY OF INVENTION

### Technical Problem

The semiconductor device obtained using the conventional manufacturing technology still cannot meet the requirement of a larger-size panel, and when the TFT in the semiconductor device is in normal operation, the electron mobility of the device is low, resulting in an incapability of meeting a requirement for a high refresh rate display.

### Solution to Technical Problem

### Technical Solution

In order to resolve the above problems, embodiments of the present disclosure provide a semiconductor device and a manufacturing method for a semiconductor device. By improving the structure of a TFT in the semiconductor device, a vertical channel TFT is formed, which effectively improves the mobility of device carriers, and ultimately improve the performance of the semiconductor device.

In order to resolve the above technical problem, the embodiments of the present disclosure provide the technical solutions as follows.

According to a first aspect of the embodiments of the present disclosure, a semiconductor device is provided, including:
a substrate, a source, a drain, a semiconductor layer, and a gate, wherein
a main body portion of the source and a main body portion of the drain are disposed on different faces, the semiconductor layer is disposed on a side of the main body portion of the source, at least part of the semiconductor layer covers the main body portion of the source, the gate is disposed on a non-main body portion of the source, and the drain is in a grid shape.

According to an embodiment of the present disclosure, the semiconductor layer includes a main body portion and an extension portion, the main body portion of the semiconductor layer is disposed on the source, and the extension portion of the semiconductor layer is disposed on a surface of the substrate.

According to an embodiment of the present disclosure, one end of the drain is disposed on the semiconductor layer, and an other end of the drain is disposed on the surface of the substrate.

According to an embodiment of the present disclosure, a projection of the gate on the substrate is located outside a projection of the drain on the substrate.

According to an embodiment of the present disclosure, the semiconductor device further includes an insulating layer, one end of the insulating layer is disposed on the source, and an other end of the insulating layer is disposed on the main body portion of the drain.

According to an embodiment of the present disclosure, the insulating layer includes a bent portion disposed between one end of the insulating layer and the other end of the insulating layer. The bent portion is in contact with a side face of the semiconductor layer as well as a side face of the drain. The gate is disposed on the insulating layer corresponding to the non-main body portion of the source and is in contact with the bent portion.

According to an embodiment of the present disclosure, the source is in a grid shape.

According to an embodiment of the present disclosure, the semiconductor device further includes a first contact electrode and a second contact electrode. The first contact electrode is disposed on a side of the drain, and the second contact electrode is disposed on a side of the source.

According to a second aspect of the embodiments of the present disclosure, a semiconductor device is provided, including:
a substrate, a source, a drain, a semiconductor layer, and a gate, wherein
a main body portion of the source and a main body portion of the drain are disposed on different faces, the semiconductor layer is disposed on a side of the main body portion of the source, at least part of the semiconductor layer covers the main body portion of the source, and the gate is disposed on a non-main body portion of the source.

According to an embodiment of the present disclosure, the semiconductor layer includes a main body portion and an extension portion, the main body portion of the semiconductor layer is disposed on the source, and the extension portion of the semiconductor layer is disposed on a surface of the substrate.

According to an embodiment of the present disclosure, one end of the drain is disposed on the semiconductor layer, and an other end of the drain is disposed on the surface of the substrate.

According to an embodiment of the present disclosure, a projection of the gate on the substrate is located outside a projection of the drain on the substrate.

According to an embodiment of the present disclosure, the semiconductor device further includes an insulating layer, one end of the insulating layer is disposed on the source, and an other end of the insulating layer is disposed on the main body portion of the drain.

According to an embodiment of the present disclosure, the insulating layer includes a bent portion disposed between one end of the insulating layer and the other end of the insulating layer. The bent portion is in contact with a side face of the semiconductor layer as well as a side face of the drain. The gate is disposed on the insulating layer corresponding to the non-main body portion of the source and is in contact with the bent portion.

According to an embodiment of the present disclosure, the source or the drain is in a grid shape.

According to an embodiment of the present disclosure, the semiconductor device further includes a first contact electrode and a second contact electrode. The first contact electrode is disposed on a side of the drain, and the second contact electrode is disposed on a side of the source.

According to a second aspect of the embodiments of the present disclosure, a method for preparing a TFT is further provided, the method including steps of:
B100: preparing a first insulating layer on a substrate;
B101: preparing a source on the first insulating layer;
B102: preparing a semiconductor layer on a side of the source, wherein at least part of the semiconductor layer covers a main body portion of the source;
B103: preparing a drain on the semiconductor layer, wherein at least part of a projection of the drain on the main body portion of the source overlaps the main body portion of the source;
B104: preparing a second insulating layer on the source, wherein the second insulating layer is in contact with a side face of the semiconductor layer and at least part of the drain; and
B105: preparing a gate on the second insulating layer.

According to an embodiment of the present disclosure, step B102 includes: processing the semiconductor layer using a blue laser annealing process.

According to an embodiment of the present disclosure, during the preparation of the drain, the drain is disposed in a grid shape.

According to an embodiment of the present disclosure, one end of the drain is disposed on the semiconductor layer, and an other end of the drain is disposed on a surface of the substrate.

### Advantages of Invention

### Beneficial Effects

Based on the above, beneficial effects of the embodiments of the present disclosure are as follows.

The embodiments of the present disclosure provide a semiconductor device and a method for preparing a semiconductor device. By improving the structure of the TFT in the semiconductor device, the semiconductor layer is disposed on the source of the TFT, and the drain is disposed on the semiconductor layer. In addition, the gate of the TFT is disposed at corresponding positions on two sides of the semiconductor layer, so as to form a vertical channel TFT, thereby improving the mobility of carriers in the TFT. When a current is transmitted in a vertical channel, even if an operation such as a bending operation is performed on the channel, the performance of the device may not be affected, thereby effectively improving the performance of the TFT.

### DESCRIPTION OF DRAWINGS

### Brief Description of Drawings

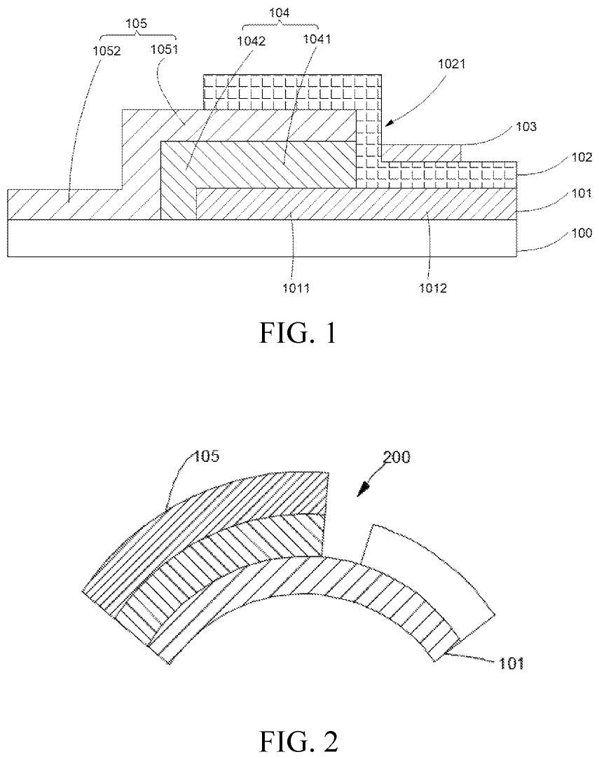

FIG. 1 is a schematic diagram of a structure of a semiconductor device according to an embodiment of the present disclosure.

FIG. 2 is a schematic diagram of a bent structure of the semiconductor device according to an embodiment of the present disclosure.

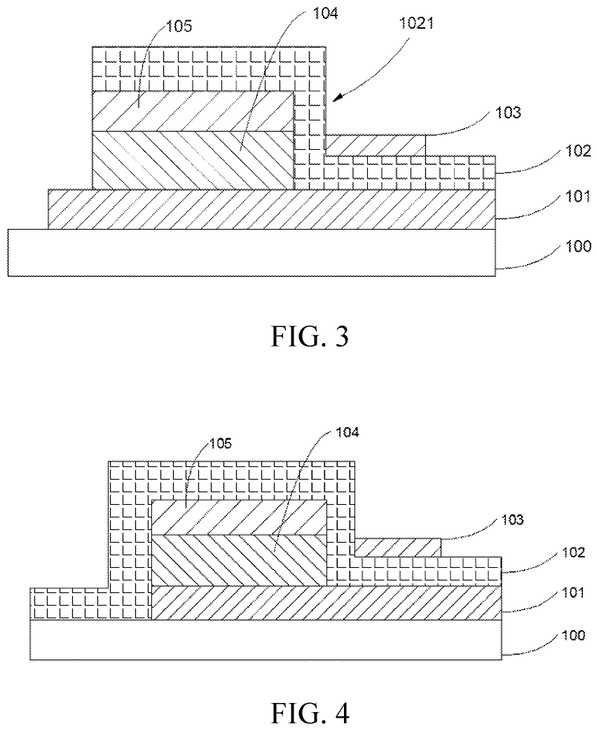

FIG. 3 is a schematic diagram of a structure of another semiconductor device according to an embodiment of the present disclosure.

FIG. 4 is a schematic diagram of a structure of another semiconductor device according to an embodiment of the present disclosure.

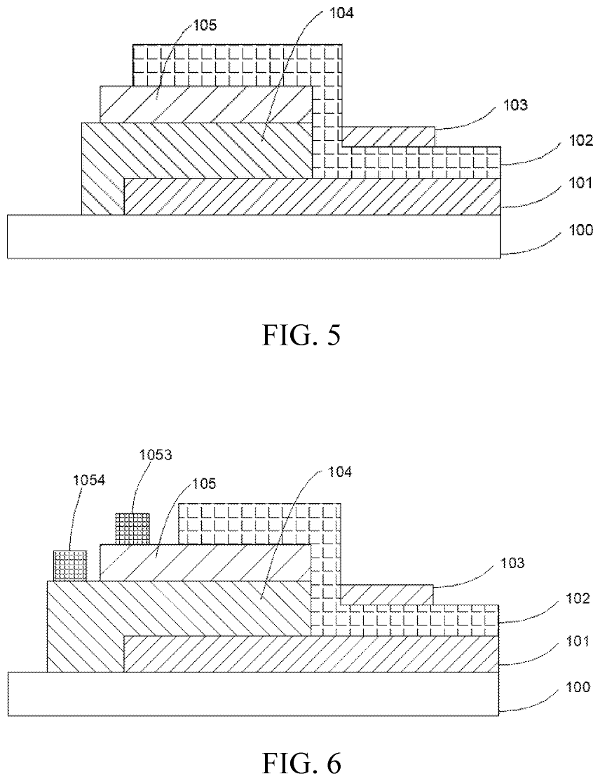

FIG. 5 is a schematic diagram of a film layer structure of the another semiconductor device according to an embodiment of the present disclosure.

FIG. 6 is a schematic diagram of a film layer structure of a semiconductor device according to an embodiment of the present disclosure.

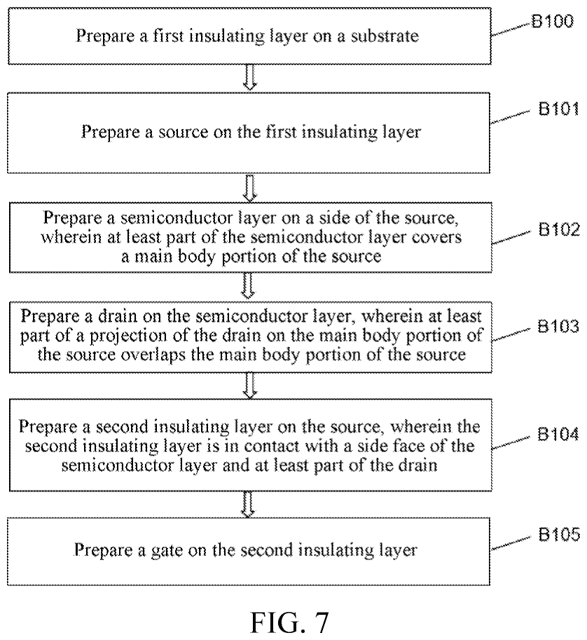

FIG. 7 is a schematic diagram of a preparation process flow of a semiconductor device according to an embodiment of the present disclosure.

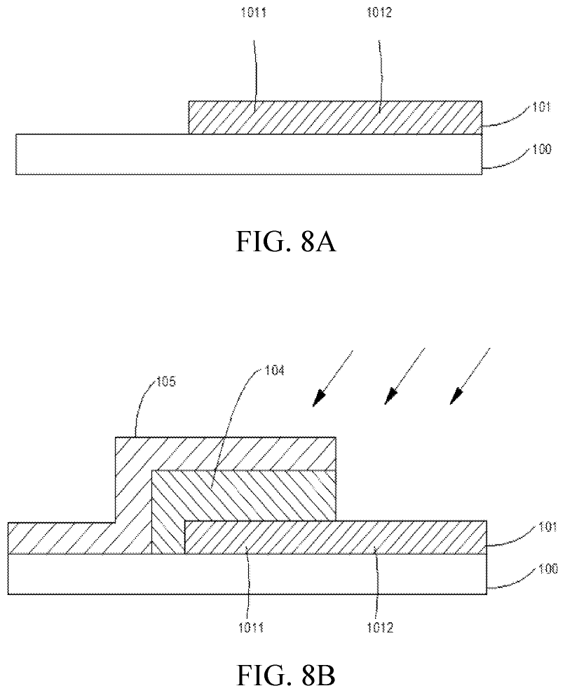

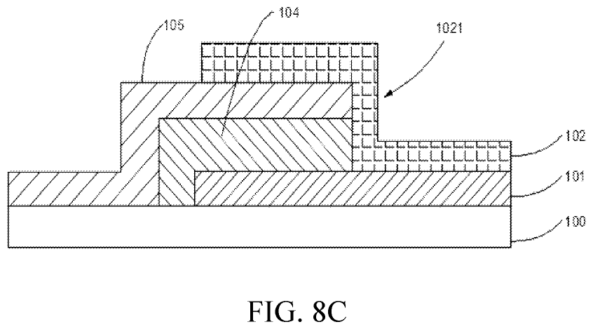

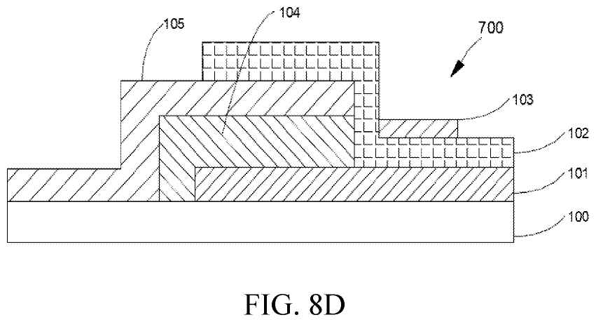

FIGS. 8A to 8D are each a schematic diagram of a film layer structure corresponding to a preparation process for a semiconductor device according to an embodiment of the present disclosure.

### EMBODIMENTS OF INVENTION

### Detailed Description of Preferred Embodiments

The following description of various embodiments is provided to exemplify the specific embodiments of the disclosure with reference to accompanying drawings.

With the continuous development of the display panel preparing technology, it is desired to prepare a panel having the optimal quality and performance. However, during the display process of the semiconductor device in the display panel, the performance of the internal TFT greatly affects the display performance of the device. Therefore, preparing a TFT having a characteristic such as higher mobility plays an important role in the display performance of the device.

As shown in FIG. 1, FIG. 1 is a schematic diagram of a structure of a semiconductor device according to an embodiment of the present disclosure. The semiconductor device includes a substrate 100, a source 101, a semiconductor layer 104, a drain 105, an insulating layer 102, and a gate 103.

In detail, when the above film layers are disposed, the source 101 is disposed on the substrate 100, the semiconductor layer 104 is disposed on the source 101, and the drain 105 is disposed on the semiconductor layer 104. In addition, a projection of the drain 105 on the substrate 100 overlaps a projection of the source 101 on the substrate. The projections may overlap completely or partially. The gate 103 is disposed on the insulating layer 102.

Preferably, as shown in FIG. 1, the source 101 includes a main body portion 1011 and a non-main body portion 1012 disposed on a side of the main body portion 1011. The drain 105 includes a main body portion 1051 of the drain and an extension portion 1052 of the drain. The semiconductor layer 104 includes a main body portion 1041 of the semiconductor layer and an extension portion 1042 of the semiconductor layer. The main body portion 1011 of the source 101 and the main body portion 1051 of the drain are disposed on different faces. The main body portion 1041 of the semiconductor layer is disposed on the source 101, and the extension portion 1042 of the semiconductor layer extends to a surface of the substrate and is in contact with the substrate.

The TFT inside the semiconductor device provided in the embodiment of the present disclosure is a vertical channel TFT. When the vertical channel TFT is applied to a bendable panel, since the channel is disposed vertically, when the panel is bent, the channel can effectively avoid the action of a bending stress.

During the arrangement, the semiconductor layer 104 is disposed on a side of the source 101, and the semiconductor layer 104 is at least partially correspondingly disposed on the source 101. As shown in FIG. 1, a part of the semiconductor layer 104, that is, the main body portion 1041 of the semiconductor layer 104 is disposed on the main body portion 1011 of the source 101. At least the main body portion 1041 covers the main body portion 1011 of the source 101. In addition, an other part of the semiconductor layer 104, that is, the extension portion 1042 of the semiconductor layer 104, extends to the surface of the substrate 100 and is in contact with the surface of the substrate 100. In this way, the semiconductor layer 104 forms an inverted “L”-like structure. As a result, different devices can be closely mated with each other, thereby effectively improving the stability and reliability of the device in use.

Preferably, since a part of the semiconductor layer 104 is disposed on the source 101, in disposing the drain 105, the drain 105 is correspondingly disposed on the semiconductor layer 104 and extended to the surface of the substrate 100. At this point, the semiconductor layer 104 and the drain 105 are both in contact with the surface of the substrate 100.

An end portion on a side of the drain 105 is flush with an end portion on a side of the semiconductor layer 104, so as to ensure consistent arrangement between different devices, thereby improving the stability of the TFT. In addition, since the drain 105 completely covers the semiconductor layer 104, a larger contact area is provided between the drain 105 and the semiconductor layer 104, which ensures an effect of change transfer in the TFT, thereby improving the performance of the TFT.

In the embodiment of the present disclosure, the insulating layer 102 is disposed on the source 101. In detail, one end of the insulating layer 102 is disposed on the non-main body portion 1012 of the source 101, and an other end of the insulating layer 102 is disposed on the main body portion 1011 of the drain 105. The insulating layer 102 further includes a bent portion 1021 disposed between the one end and the other end of the insulating layer 102. The bent portion 1021 is in contact with side faces of the semiconductor layer 104 and the drain 105. In this way, the insulating layer 102 can effectively block a part of the source 101, the semiconductor layer 104, and the drain 105, and the gate 103 is disposed on the insulating layer 102 corresponding to the non-main body portion 1012 of the source 101. In the embodiment of the present disclosure, the gate 103 may be in contact with the bent portion 1021, or a specific gap is reserved between the gate 103 and the bent portion 1021, so as to ensure the performance of the TFT. When a control signal is applied to the TFT in the embodiment of the present disclosure, since the drain 105 of the TFT in the embodiment of the present disclosure is disposed on the source 101, and the semiconductor layer 104 is disposed between the drain 105 and the source 101, a channel area of the TFT is a vertical channel. Carriers in the TFT are to be transferred in the vertical channel area.

Further, as shown in FIG. 2, FIG. 2 is a schematic diagram of a bent structure of a semiconductor device according to an embodiment of the present disclosure. When the semiconductor device in the embodiment of the present disclosure is applied to a flexible panel, since the TFT inside the semiconductor device is a vertical channel TFT, a longitudinal crack 200 may be generated during the bending process, and the generated longitudinal crack 200 may not affect the charge transfer in a vertical direction. Therefore, the charge can still be normally transferred from the drain 105 to the source 101. Therefore, the bending process has little effect on the channel current, thereby effectively improving the bending resistance of the back panel.

As shown in FIG. 3, FIG. 3 is a schematic diagram of a structure of another semiconductor device according to an embodiment of the present disclosure. In detail, the semiconductor device includes a substrate 100, a source 101, a semiconductor layer 104, a drain 105, an insulating layer 102, and a gate 103.

The source 101 is disposed on the substrate 100, and the semiconductor layer 104 is disposed on the source 101. Compared with the structure of the TFT in FIG. 1, the semiconductor layer 104 in the embodiment of the present disclosure is completely disposed on the source 101, and the semiconductor layer 104 is not in contact with the substrate. Further, the drain 105 is disposed on the semiconductor layer 104. One end of the insulating layer 102 is disposed on the source 101, an other end of the insulating layer 102 extends to the drain 105, and the insulating layer 102 is simultaneously in contact with corresponding side faces of the semiconductor layer 104 and the drain 105.

Finally, the gate 103 is disposed on the insulating layer 102. In disposing the gate 103, the gate 103 is disposed on a side of the semiconductor layer 104. When the gate 103 is disposed on the side of the semiconductor layer 104, the gate 103 and the source 101 may form a capacitor structure, so as to ensure the normal operation of the TFT. Further, in disposing the gate 103, it can be ensured that a projection of the gate 103 on the substrate 100 and a projection of the drain 105 on the substrate 100 do not overlap.

According to the structures in FIG. 1 and FIG. 2, it can be seen that the structure on a left side of the TFT in FIG. 3 is further improved, so that a size of the TFT is further reduced, but the performance of the TFT is not affected. When the TFT is bent, the vertical channel TFT still has better performance, thereby effectively providing the use performance of the device.

As shown in FIG. 4, FIG. 4 is a schematic diagram of a structure of another semiconductor device according to an embodiment of the present disclosure. The semiconductor device includes a substrate 100, a source 101, a semiconductor layer 104, a drain 105, an insulating layer 102, and a gate 103.

In detail, the source 101 is disposed on the substrate 100, and the semiconductor layer 104 is disposed on the source 101. In the present embodiment, the semiconductor layer 104 is disposed on a side of the source 101. In addition, the drain 105 is disposed on the semiconductor layer 104, the insulating layer 102 is disposed on the source 101, and one end of the insulating layer 102 is disposed on the source 101. The insulating layer 102 covers the drain 105. An other end of the insulating layer 102 extends to the substrate 100 and is in contact with a surface of the substrate 100. Further, the insulating layer 102 is correspondingly in contact with a side face on each of two ends of the semiconductor layer 104 and the drain 105. At this point, the semiconductor layer 104 and the drain 105 are completely covered by the insulating layer 102. When the TFT operates normally, carriers are transferred from the drain 105 to the source 101. Since the TFT in the embodiment of the present disclosure is a vertical channel TFT, even if the TFT is bent, the performance of the TFT is not affected.

In detail, a thickness of the semiconductor layer 104 is the same as a channel length of the TFT. In addition, the gate 103 is disposed on the insulating layer 102, and the gate 103 is disposed on the insulating layer 102 corresponding to the source 101.

In the embodiments of the present disclosure, in order to ensure that the source 101 and drain 105 of the TFT are connected to other film layers, preferably, a connecting electrode may be disposed on each of one sides of the source 101 and the drain 105, or a corresponding via hole is provided on each of one sides of the source 101 and the drain 105, and the source 101 and the drain 105 are electrically connected to other film layers through the via holes, thereby achieving the function of the TFT.

Compared with the TFT in FIG. 3, in the embodiment of the present disclosure, the insulating layer 102 has a larger arrangement area and region. In this way, the insulating layer 102 can block the semiconductor layer 104 and the drain 105 as much as possible, thereby preventing problems such as mutual interference between different devices from occurring, and improving various performances of the TFT.

When the TFT is disposed to have the structure of the vertical channel TFT shown in FIG. 3, the gate 103 is disposed on a side of the insulating layer 102, and the gate electrode 103 is disposed on the corresponding source 101. In this way, a capacitance storage structure can be formed between the gate 103 and the corresponding source 101.

In the embodiment of the present disclosure, materials of the source 101 and the drain 105 may be selected from metal, conductive materials, metal alloys, and the like. The conductive material may be indium tin oxide, or the like, and the materials of the source 101 and the drain 105 may be the same. Further, a material of the semiconductor layer 104 may be InOx, IGZO, or ZnO. Moreover, a material of the insulating layer 102 may be an insulating material, such as aluminum oxide, to ensure the insulating effect of the insulating layer 102.

As shown in FIG. 5, FIG. 5 is a schematic diagram of a film layer structure of another semiconductor device according to an embodiment of the present disclosure. The semiconductor device includes a substrate 100, a source 101, a semiconductor layer 104, a drain 105, an insulating layer 102, and a gate 103.

In detail, the source 101 is disposed on the substrate 100, the semiconductor layer 104 is disposed on the source 101, and a side of the semiconductor layer 104 is disposed on the semiconductor layer 104. An other end of the semiconductor layer 104 extends to the substrate 100 and is in contact with a surface of the substrate 100, so as to connect the semiconductor layer 104 to the source 101.

In addition, the drain 105 is disposed on the semiconductor layer 104, and a projected area of the drain 105 on the semiconductor layer 104 is less than an area of an upper surface of the semiconductor layer 104. That is to say, the drain 105 is completely disposed on the semiconductor layer 104.

Further, the insulating layer 102 is disposed on the source 101. In detail, one end of the insulating layer 102 is disposed on the substrate 100, and the insulating layer 102 is in contact with a side face on one end of the semiconductor layer 104 as well as a side face on one end of the drain 105. Moreover, an other end of the insulating layer 102 is disposed on the drain 105, so as to achieve a blocking effect between different film layers.

Preferably, the gate 103 is disposed on a side of the insulating layer 102, and a projection of the gate 103 on the substrate 100 does not coincide with a projection of the drain 105 on the substrate 100. That is to say, the projection of the gate 103 on the substrate 100 is located outside the projection of the drain 105 on the substrate 100. In this way, the gate 103 and the source 101 can form a capacitor structure. In addition, the source 101, the semiconductor layer 104, and the drain 105 form a vertical structure type TFT. When the TFT is bent, since the TFT is a vertical type TFT, bending in a longitudinal direction will not affect the performance of the TFT, thereby effectively improving the performance of the TFT.

Optionally, in order to further improve the bending performance of the semiconductor device, the drain 105 or the source 101 in the embodiment of the present disclosure may further be disposed in a grid-shaped structure. When the source 101 and the drain 105 in the grid-shaped structure are being bent, an internal bending stress is relatively small, thereby effectively improving the performance of the TFT.

As shown in FIG. 6, FIG. 6 is a schematic diagram of a film layer structure of a semiconductor device according to an embodiment of the present disclosure. The semiconductor device includes a substrate 100, a source 101, a semiconductor layer 104, a drain 105, an insulating layer 102, and a gate 103.

Further, the source 101 is disposed on the substrate 100, one end of the semiconductor layer 104 is disposed on the source 101, and one end of the semiconductor layer 104 is disposed on a side of the source 101. An other end of the semiconductor layer 104 extends to a surface of the substrate 100 and is in contact with the surface of the substrate 100.

The drain 105 is disposed on the semiconductor layer 104, and a projection of the drain 105 on the substrate 100 is located in a projection area of the semiconductor layer 104 on the substrate 100. In addition, one end of the drain 105 is flush with the one end of the semiconductor layer 104.

One end of the insulating layer 102 is disposed on the source 101, an other end of the insulating layer 102 is disposed on the drain 105, and the insulating layer 102 is simultaneously in contact with side faces of the one ends of the semiconductor layer 104 and the drain 105. In addition, the gate 103 is disposed on the insulating layer 102, so that it can be ensured that a projection of the gate 103 on the substrate 100 and the projection of the drain 105 on the substrate 100 do not coincide with each other.

Preferably, the semiconductor device further includes a first contact electrode 1053 and a second contact electrode 1054. The second contact electrode 1054 is disposed on the semiconductor layer 104, and the first contact electrode 1053 is disposed on the drain 105. In detail, the second contact electrode 1054 is disposed on a side of the semiconductor layer 104, and the first contact electrode 1053 is disposed on a side of the drain 105. Therefore, the electrical connection to other film layers can be achieved using the first contact electrode 1053 and the second contact electrode 1054.

Moreover, in the embodiment of the present disclosure, the drain 105 is disposed opposite to the source 101 to form a vertical channel TFT. At this point, a length of a TFT channel is a thickness of the semiconductor layer 104, and the thickness can be accurately adjusted according to actual requirements. The electron mobility in the semiconductor layer 104 is higher than that in a channel of a general TFT, so that the performance of the TFT in the embodiment of the present disclosure is more stable. Because the TFT is a vertical channel TFT, a size of the TFT can be further reduced, thereby significantly reducing an area of pixels, and also significantly improving the electrical properties of the TFT.

Further, an embodiment of the present disclosure further provides a method for preparing a TFT. As shown in FIG. 7, FIG. 7 is a schematic diagram of a preparation process flow of a TFT according to an embodiment of the present disclosure. FIGS. 8A to 8D are each a schematic diagram of a film layer structure corresponding to a preparation process for a semiconductor device according to an embodiment of the present disclosure.

In detail, the preparation process includes steps as follows.

B100: Prepare a first insulating layer on a substrate.

B101: Prepare a source on the first insulating layer.

As shown in FIG. 8A, a substrate 100 is provided. The substrate 100 in the embodiment of the present disclosure may include a multilayer structure. For example, the substrate 100 includes a first base plate and a first insulating layer disposed on the first base plate. The first base plate may include a glass base plate or a film material, such as polyimide, and the first insulating layer may include an insulating film material, such as silicon dioxide, silicon nitride, and the like.

After the substrate 100 is prepared, a source 101 is prepared on the substrate 100. In preparing the source 101, the source 101 may be disposed on a side of the substrate 100, and one end of the source 101 may be flush with an end of the substrate 100.

B102: Prepare a semiconductor layer on a side of the source, wherein at least part of the semiconductor layer covers a main body portion of the source.

B103: Prepare a drain on the semiconductor layer, wherein at least part of a projection of the drain on the main body portion of the source overlaps the main body portion of the source.

B104: Prepare a second insulating layer on the source, wherein the second insulating layer is in contact with a side face of the semiconductor layer and at least part of the drain.

As shown in FIG. 8B, after the preparation of the source 101 is completed, a semiconductor layer 104 is prepared on the source 101. In preparing the semiconductor layer 104, the semiconductor layer 104 is disposed at a position on a side of the source 101. A part of the semiconductor layer 104 is disposed on the side of the source 101, and an other part of the semiconductor layer 104 extends to the substrate 100 and is in contact with a surface of the substrate 100. In this way, the semiconductor layer 104 is firmly fixed in the device.

After the preparation of the semiconductor layer 104 is completed, the drain 105 is continuously prepared on the semiconductor layer 104. One end of the drain 105 is flush with one end of the semiconductor layer 104, and an other end of the drain 105 can extend to the surface of the substrate 100 and is in contact with the surface of the substrate 100. At least part of the projection of the drain 105 on the main body portion 1011 of the source 101 overlaps the main body portion 1011 of the source 101. The drain 105 completely covers the semiconductor layer 104, and at least part of the projection of the drain 105 on the main body portion 1011 of the source 101 overlaps the main body portion 1011 of the source 101.

Further, the preparing a semiconductor layer 104 further includes a step of: processing the semiconductor layer 104 using a blue laser annealing process, wherein during the laser annealing, energy of a laser may be selected according to a thickness of an actual film, and specific values may be selected according to different product requirements. Moreover, during the laser annealing, a scanning speed of the laser on the semiconductor layer 104 is controlled to ensure that the semiconductor layer can be fully annealed to obtain TFTs having different crystalline properties, finally achieving the goal of improving device performance.

Preferably, in preparing the drain 105, only a part of the drain 105 can be disposed. That is to say, the drain 105 is only disposed in a corresponding area on the semiconductor layer 104, so as to simplify the structure in the TFT and reduce the size of the TFT.

As shown in FIG. 8C, after the preparation of the drain 105 is completed, the insulating layer 102 is continuously prepared, and the insulating layer 102 is a second insulating layer. One end of the insulating layer 102 is disposed on the source 101, and an other end of the insulating layer 102 extends to a surface of the drain 105 and is in contact with the drain 105. The insulating layer 102 further includes a bent portion 1021. The bent portion 1021 is in contact with a side face on each of one ends of the semiconductor layer 104 and the drain 105. After the preparation of the insulating layer 102 is completed, the insulating layer 102 forms a stepped structure, thereby achieving blocking and insulating effects between different film layers.

B105: Prepare a gate on the second insulating layer.

As shown in FIG. 8D, after the preparation of the insulating layer 102 is completed, a gate 103 of the TFT is prepared. The gate 103 is disposed on the insulating layer 102, and the gate 103 is disposed on the insulating layer 102 corresponding to a first area 700 of the source 101. In this way, the gate 103 and the source 101 can form a capacitor structure, thereby achieving the charge storage.

In the embodiment of the present disclosure, a projection of the gate 103 on the substrate 100 and a projection of the drain 105 on the substrate 100 do not overlap. In addition, since the drain 105 is disposed on the source 101, the TFT is a vertical channel TFT. A length of a channel is a thickness of the semiconductor layer 104 disposed between the drain 105 and the source 101. After the TFT is bent, since the TFT is a vertical channel TFT, carriers can still be transferred normally in the corresponding channel, thereby effectively ensuring the performance of the TFT.

Further, the embodiment of the present disclosure further provides a light-emitting device. The light-emitting device includes the TFT provided in the embodiment of the present disclosure. The TFT is a vertical channel TFT. After the light-emitting device is bent, the device still has a desirable light-emitting performance.

The semiconductor device and the method for preparing the semiconductor device are described in detail above. The principles and implementations of the present disclosure are described by using specific examples in the present disclosure, and the descriptions of the embodiments are only intended to help understand the methods and core ideas of the present disclosure. It should be understood by persons of ordinary skill in the art that modifications can be made to the technical solutions described in the foregoing embodiments, or equivalent replacements can be made to some technical features in the technical solutions, as long as such modifications or replacements do not cause the essence of corresponding technical solutions to depart from the scope of the technical solutions of the embodiments of the present invention.

What is claimed is:

1. A semiconductor device, comprising:
a substrate, a source, a drain, a semiconductor layer, and a gate, wherein
a main body portion of the source and a main body portion of the drain are disposed on different faces, the semiconductor layer is disposed on a side of the main body portion of the source, at least part of the semiconductor layer covers the main body portion of the source, the gate is disposed on a non-main body portion of the source, and the drain is in a grid shape.

2. The semiconductor device as claimed in claim 1, wherein the semiconductor layer comprises a main body portion and an extension portion, the main body portion of the semiconductor layer is disposed on the source, and the extension portion of the semiconductor layer is disposed on a surface of the substrate.

3. The semiconductor device as claimed in claim 2, wherein one end of the drain is disposed on the semiconductor layer, and an other end of the drain is disposed on the surface of the substrate.

4. The semiconductor device as claimed in claim 1, wherein a projection of the gate on the substrate is located outside a projection of the drain on the substrate.

5. The semiconductor device as claimed in claim 4, wherein the semiconductor device further comprises an insulating layer, one end of the insulating layer is disposed on the source, and an other end of the insulating layer is disposed on the main body portion of the drain.

6. The semiconductor device as claimed in claim 5, wherein the insulating layer comprises a bent portion disposed between one end of the insulating layer and the other end of the insulating layer, the bent portion is in contact with a side face of the semiconductor layer as well as a side face of the drain, and the gate is disposed on the insulating layer corresponding to the non-main body portion of the source and is in contact with the bent portion.

7. The semiconductor device as claimed in claim 1, wherein the source is in a grid shape.

8. The semiconductor device as claimed in claim 1, wherein the semiconductor device further comprises a first contact electrode and a second contact electrode, the first contact electrode is disposed on a side of the drain, and the second contact electrode is disposed on a side of the source.

9. A semiconductor device, comprising:
a substrate, a source, a drain, a semiconductor layer, and a gate, wherein
a main body portion of the source and a main body portion of the drain are disposed on different faces, the semiconductor layer is disposed on a side of the main body portion of the source, at least part of the semiconductor layer covers the main body portion of the source, and the gate is disposed on a non-main body portion of the source.

10. The semiconductor device as claimed in claim 9, wherein the semiconductor layer comprises a main body portion and an extension portion, the main body portion of the semiconductor layer is disposed on the source, and the extension portion of the semiconductor layer is disposed on a surface of the substrate.

11. The semiconductor device as claimed in claim 10, wherein one end of the drain is disposed on the semiconductor layer, and an other end of the drain is disposed on the surface of the substrate.

12. The semiconductor device as claimed in claim 9, wherein a projection of the gate on the substrate is located outside a projection of the drain on the substrate.

13. The semiconductor device as claimed in claim 12, wherein the semiconductor device further comprises an insulating layer, one end of the insulating layer is disposed on the source, and an other end of the insulating layer is disposed on the main body portion of the drain.

14. The semiconductor device as claimed in claim 13, wherein the insulating layer comprises a bent portion disposed between one end of the insulating layer and the other end of the insulating layer, the bent portion is in contact with a side face of the semiconductor layer as well as a side face of the drain, and the gate is disposed on the insulating layer corresponding to the non-main body portion of the source and is in contact with the bent portion.

15. The semiconductor device as claimed in claim 9, wherein the source is in a grid shape.

16. The semiconductor device as claimed in claim 9, wherein the semiconductor device further comprises a first contact electrode and a second contact electrode, the first contact electrode is disposed on a side of the drain, and the second contact electrode is disposed on a side of the source.

17. A method for preparing a semiconductor device, the method comprising steps of:
B100: preparing a first insulating layer on a substrate;
B101: preparing a source on the first insulating layer;
B102: preparing a semiconductor layer on a side of the source, wherein at least part of the semiconductor layer covers a main body portion of the source;
B103: preparing a drain on the semiconductor layer, wherein at least part of a projection of the drain on the main body portion of the source overlaps the main body portion of the source;
B104: preparing a second insulating layer on the source, wherein the second insulating layer is in contact with a side face of the semiconductor layer and at least part of the drain; and
B105: preparing a gate on the second insulating layer.

18. The method for preparing a semiconductor device as claimed in claim 17, wherein step B102 comprises: processing the semiconductor layer using a blue laser annealing process.

19. The method for preparing a semiconductor device as claimed in claim 17, wherein during the preparation of the drain, the drain is disposed in a grid shape.

20. The method for preparing a semiconductor device as claimed in claim 18, wherein one end of the drain is disposed on the semiconductor layer, and an other end of the drain is disposed on a surface of the substrate.
